(19) United States
(12) Patent Application Publication
(10) Pub. No.: US 2024/0413799 A1
(43) Pub. Date: Dec. 12, 2024

(54) HIGH FREQUENCY AMPLIFIER AND MATCHING CIRCUIT

(71) Applicant: Mitsubishi Electric Corporation, Tokyo (JP)

(72) Inventors: Eigo Kuwata, Tokyo (JP); Takashi Yamasaki, Tokyo (JP); Takumi Sugitani, Tokyo (JP)

(73) Assignee: Mitsubishi Electric Corporation, Tokyo (JP)

(21) Appl. No.: 18/809,657

(22) Filed: Aug. 20, 2024

Related U.S. Application Data
(63) Continuation of application No. PCT/JP2022/017136, filed on Apr. 6, 2022.

(51) Int. Cl. H03F 3/19; H01L 23/66; H03F 1/56

(52) U.S. Cl. CPC H03F 3/19; H01L 23/66; H03F 1/56; H01L 2223/6611; H01L 2223/6655

(57) ABSTRACT

Disclosed is a high frequency amplifier including an input matching circuit, an output matching circuit, and m (m is an integer greater than or equal to three) amplification elements, in which at least one of the input and output matching circuits includes: a comb structure having m lines whose one ends are connected on a one to one basis to the m amplification elements, and a joint part where the other ends of the m lines are joined together; and resistors each provided between adjacent lines out of the m lines, and in which multiple spacings each formed between adjacent lines of the m lines include a first spacing and a second spacing wider than the first spacing.

### CROSS REFERENCE TO RELATED APPLICATION

This application is a Continuation of PCT International Application No. PCT/JP2022/017136, filed on Apr. 6, 2022, which is hereby expressly incorporated by reference into the present application.

### TECHNICAL FIELD

The present disclosure relates to a high frequency amplifier and a matching circuit.

### BACKGROUND ART

A high frequency amplifier described in Patent Literature 1 includes an amplification element, an input matching circuit provided on an input side of this amplification element, and an output matching circuit provided on an output side of this amplification element. In this high frequency amplifier, a slit is provided in the input matching circuit in order to reduce an amplitude difference and a phase difference in a high frequency signal supplied to each cell of the amplification element. Further, in this high frequency amplifier, by placing a resistor in the slit, isolation between cells of the amplification element is improved, and oscillations are suppressed.

### CITATION LIST

### Patent Literature

Patent Literature 1: JP 2010-219654 A

### SUMMARY OF INVENTION

### Technical Problem

In the high frequency amplifier described in Patent Literature 1, in the case where the width of the above-mentioned slit is narrow, when a high frequency current in an opposite direction occurs between both the ends of the input matching circuit between which the slit is sandwiched, a coupling over the slit occurs and the high frequency current flows through this coupling. In that case, in this high frequency amplifier, a flow channel (loop) through which the high frequency current circulates among the input matching circuit, the amplification element, and the output matching circuit is formed.

Because in this flow channel, the high frequency current flows not through the resistor placed in the slit, but through the above-mentioned coupling, the high frequency current does not attenuate even though the resistor is placed in the slit. As a result, there is a possibility that the high frequency current is amplified by the amplification element, and the high frequency amplifier oscillates as a result. Therefore, as a method of suppressing such an oscillation, a method of increasing the width of the slit can be considered.

On the other hand, in order to make the high frequency amplifier be a high power one, it is necessary to reduce the impedances of the amplification element and the matching circuits (the input and output matching circuits). However, when the width of the slit provided in the input matching circuit is increased in the above-mentioned high frequency amplifier, the impedance of the input matching circuit is high. More specifically, in the above-mentioned conventional high frequency amplifier, there are limits to how much the impedances of the matching circuits can be reduced while oscillations are suppressed.

It is an object of the present disclosure to provide a high frequency amplifier that can implement both the suppression of oscillations, and an impedance reduction in matching circuits.

### Solution to Problem

A high frequency amplifier according to the present disclosure includes an input matching circuit, an output matching circuit, and m amplification elements, in which m is an integer greater than or equal to three, and at least one of the input and output matching circuits includes: a comb structure having m lines whose one ends are connected on a one to one basis to the m amplification elements, and a joint part where the other ends of the m lines are joined together; and resistors each provided between adjacent lines out of the m lines, and multiple spacings each formed between adjacent lines of the m lines include a first spacing and a second spacing wider than the first spacing.

### Advantageous Effects of Invention

According to the present disclosure, because the configuration is provided as above, it is possible to implement both the suppression of oscillations, and an impedance reduction in the matching circuits.

### BRIEF DESCRIPTION OF DRAWINGS

FIG. 1 is a view showing an example (m=4) of the configuration of a high frequency amplifier according to Embodiment 1;

FIG. 2 is a view explaining an advantageous effect of the high frequency amplifier according to Embodiment 1;

FIG. 3 is a view explaining the advantageous effect of the high frequency amplifier according to Embodiment 1;

FIG. 4 is a view showing an example of a comparison of flows of high frequency currents in a conventional high frequency amplifier with those shown in FIG. 2;

FIG. 5 is a view showing an example of a comparison of flows of high frequency currents in the conventional high frequency amplifier with those shown in FIG. 3;

FIG. 6 is a view showing an example of a configuration in which wires are eliminated in the high frequency amplifier according to Embodiment 1;

FIG. 7 is a view showing another example of the configuration of the high frequency amplifier in Embodiment 1;

FIG. 8 is a view showing another example (m=3) of the configuration of the high frequency amplifier in Embodiment 1;

FIG. 9 is a view explaining an advantageous effect of the high frequency amplifier shown in FIG. 8;

FIG. 10 is a view showing an example of a comparison of flow of high frequency currents in a conventional high frequency amplifier with those shown in FIG. 8;

FIG. 11 is a view showing an example of a configuration in which wires are eliminated in the high frequency amplifier shown in 8;

FIG. 12 is a view showing another example of the configuration of the high frequency amplifier shown in FIG. 8;

FIG. 13 is a view showing another example (m=5) of the configuration of the high frequency amplifier in Embodiment 1;

FIG. 14 is a view showing an example of flows of high frequency currents in the high frequency amplifier shown in FIG. 8; and

FIG. 15 is a view explaining an example of the configuration of a high frequency amplifier according to Embodiment 2.

### DESCRIPTION OF EMBODIMENTS

Hereinafter, the embodiments of the present disclosure will be explained in detail while referring to the drawings.

### Embodiment 1

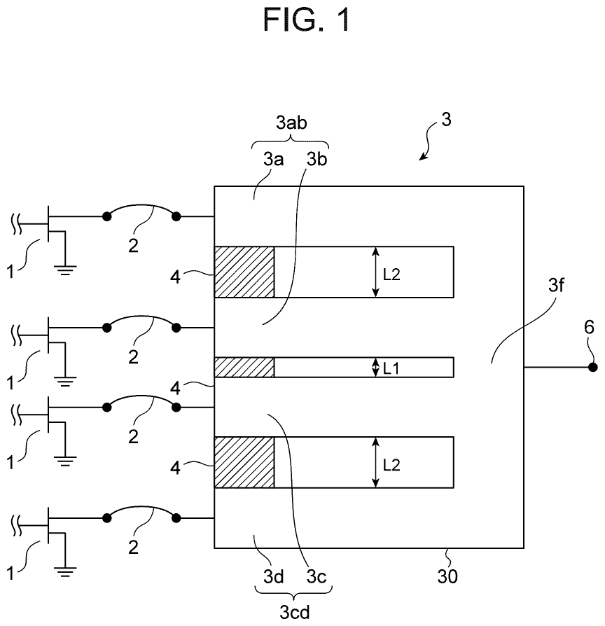

FIG. 1 is a view showing an example of the configuration of a high frequency amplifier according to Embodiment 1. The high frequency amplifier according to Embodiment 1 includes amplification elements 1, wires 2, and a transmission line 3, as shown in FIG. 1. Although in FIG. 1, a configuration on an output terminal (denoted by reference sign 6 of FIG. 1) side of the high frequency amplifier is shown as an example, an input terminal (not illustrated) side of the high frequency amplifier can also be considered to have the same configuration as that shown in FIG. 1.

The amplification elements 1 each amplify a high frequency current inputted from the input terminal of the high frequency amplifier, and each include, for example, a transistor or a field effect transistor. In the high frequency amplifier according to Embodiment 1, m (m is an integer greater than or equal to three) amplification elements 1 are provided. In FIG. 1, an example in which four amplification elements 1 are provided (m=4) is shown.

The wires 2 are metal thin wires which connect an output terminal of each of the four amplification elements 1, and an end of a corresponding one of lines 3a, 3b, 3c, and 3d which make up the transmission line 3.

The transmission line 3 is formed on a dielectric board provided on output terminal sides of the amplification elements 1, and configures an output matching circuit provided on the output terminal sides of the amplification elements 1. In FIG. 1, for the sake of simplicity, the illustration of the dielectric board is omitted, and only the transmission line 3 formed on this dielectric board is shown.

The transmission line 3 includes: a comb structure 30 having the four lines 3a, 3b, 3c, and 3d arranged in parallel and a joint part 3f; and resistors 4 each provided between adjacent lines out of the four lines, as shown in FIG. 1.

The ends of the four lines 3a, 3b, 3c, and 3d are connected to the four amplification elements on a one to one basis via the wires 2, as shown in FIG. 1. Further, the other ends of the four lines 3a, 3b, 3c, and 3d are joined together, thereby forming the joint part 3f.

Further, in the transmission line 3, multiple spacings each formed between adjacent lines of the four lines 3a, 3b, 3c, and 3d include a first spacing L1 and second spacings L2 wider than the first spacing L1.

For example, in the transmission line 3, each of line pairs is configured by combining adjacent two lines, out of the above-mentioned four lines, from an end of the transmission line in order along an upward or downward direction of FIG. 1, i.e. a direction in which the lines are arranged adjacent to each other. For example, in FIG. 1, in the transmission line 3, the lines 3a and line 3b make up a line pair 3ab, and the lines 3c and 3d make up a line pair 3cd.

Further, in the transmission line 3, the spacing between the line pairs in the upward or downward direction of FIG. 1, i.e. the direction in which the lines are arranged adjacent to each other is the first spacing L1, and the spacing between the lines which make up each of the line pairs in the direction is the second spacing L2 wider than the first spacing L1. For example, in FIG. 1, the spacing between the line pairs 3ab and 3cd is the first spacing L1, and the spacing between the lines 3a and 3b and the spacing between the lines 3c and 3d are the second spacings L2.

Although in FIG. 1, the example in which the second spacings L2 formed at the two positions are nearly identical is shown, the second spacings L2 do not necessarily have to be identical. For example, the second spacings L2 formed at the two positions may be different as long as all of the second spacings L2 formed at the two positions are wider than the first spacing L1. However, it is desirable that the second spacings L2 are formed sufficiently wide to be able to at least prevent the electrical coupling between the lines which form each of the second spacings L2.

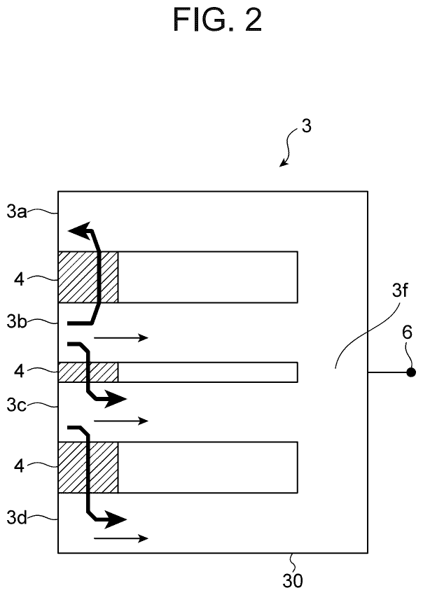

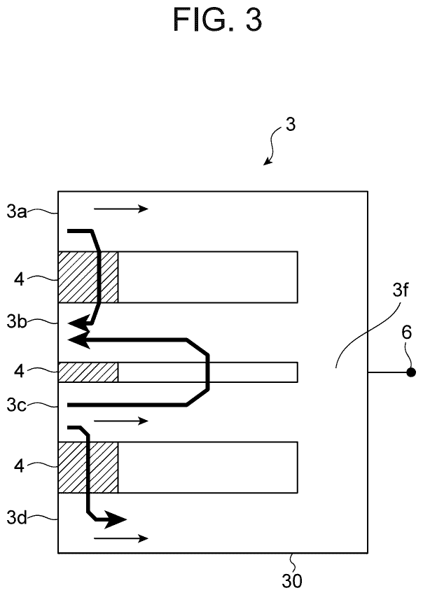

Next, an advantageous effect of the high frequency amplifier according to Embodiment 1 will be explained while referring to FIGS. 2 and 3.

FIG. 2 shows a case in which the amplification element 1 connected to the endmost line 3a, out of the four amplification elements 1, operates with an opposite phase, and the amplification elements 1 connected to the other lines 3b, 3c, and 3d operate with the same phase. In this case, in the transmission line 3, a high frequency current with an opposite phase (in an opposite direction) is applied only to the line 3a from the amplification element 1.

The state in which one of the amplification elements 1 operates with an opposite phase, as mentioned above, may occur when a signal containing a noise component whose phase changes at random is inputted to an input terminal of an input matching circuit (not illustrated), for example.

In FIG. 2, it is assumed that the direction of the high frequency current with the opposite phase (the opposite direction) which is applied from the amplification element 1 to the line 3a is right to left, and the direction of high frequency currents with the same phase which are applied from the amplification elements 1 to the lines 3b, 3c, and 3d is left to right. In FIG. 2, the high frequency currents with the same phase applied from the amplification elements 1 to the lines 3b, 3c, and 3d are denoted by thin arrows. Further, in FIG. 2, for the sake of simplicity, the illustration of the amplification elements 1 and the wires 2 is omitted.

In this case, because in the transmission line 3, the second spacing L2 which is sufficiently wide to be able to at least prevent the electrical coupling between the lines 3a and 3b is formed between the lines 3a and 3b, no coupling occurs between these lines. Therefore, a high frequency current applied to the line 3b flows through the resistor 4 provided between the lines 3a and 3b into the line 3a, as shown by a wide arrow in FIG. 2, and attenuates because it flows through this resistor 4. Therefore, in the high frequency amplifier, the high frequency current attenuates and oscillations are suppressed.

Further, even when a slight coupling occurs between the lines 3a and 3b, if the impedance of the resistor 4 provided between these lines is lower than the impedance between the lines at the point of this coupling, the high frequency current applied to the line 3b flows through the resistor 4 provided between the lines into the line 3a, instead of flowing through the above-mentioned coupling point into the line 3a. Therefore, in the high frequency amplifier, the high frequency current attenuates and oscillations are suppressed even in this case.

In addition, a case in which a circulation flow passage (loop) in which part or all of the high frequency current applied to the line 3b flows not through the resistor 4 provided between the lines 3a and 3b but through the above-mentioned coupling point into the line 3a, and then passes through the amplification element 1 and the input matching circuit and is applied again to the line 3b of the output matching circuit (transmission line 3) is formed is considered.

In this case, the amplified high frequency current applied to the line 3b flows through the resistor 4 provided between the lines 3b and 3c into the line 3c, as shown by a wide arrow in FIG. 2. Further, the high frequency current flowing into the line 3c flows, from the line 3c, through the resistor 4 provided between the lines 3c and 3d, into the line 3d.

As mentioned above, the high frequency current applied to the line 3b flows through the resistors 4 into the adjacent lines (the lines 3c and 3d), and hence attenuates. Therefore, in the high frequency amplifier according to Embodiment 1, even when a circulation flow passage (loop) as above is formed, the increase in the high frequency current can be prevented, and oscillations can be suppressed.

Next, FIG. 3 shows a case in which the amplification element 1 connected to the line 3b, out of the four amplification elements 1, operates with an opposite phase, and the amplification elements 1 connected to the other lines 3a, 3c, and 3d operate with the same phase. In this case, in the transmission line 3, a high frequency current with an opposite phase is applied only to the line 3b from the amplification element 1.

Also in FIG. 3, it is assumed that the direction of the high frequency current with the opposite phase (the opposite direction) which is applied from the amplification element 1 to the line 3b is right to left, and the direction of high frequency currents with the same phase which are applied from the amplification elements 1 to the lines 3a, 3c, and 3d is left to right, like in FIG. 2. Further, in FIG. 3, for the sake of simplicity, the illustration of the amplification elements 1 and the wires 2 is omitted.

In this case, because in the transmission line 3, the second spacing L2 which is sufficiently wide to be able to at least prevent the electrical coupling between the lines 3a and 3b is formed between the lines 3a and 3b, no coupling occurs between these lines. Therefore, a high frequency current applied to the line 3a flows through the resistor 4 provided between the lines 3a and 3b into the line 3b, as shown by a wide arrow in FIG. 3, and attenuates because it flows through this resistor 4. Therefore, in the high frequency amplifier, the high frequency current attenuates and oscillations are suppressed.

Further, even when a slight coupling occurs between the lines 3a and 3b, if the impedance of the resistor 4 provided between these lines is lower than the impedance between the lines at the point of this coupling, the high frequency current applied to the line 3a flows through the resistor 4 provided between the lines into the line 3b, instead of flowing through the above-mentioned coupling point into the line 3b. Therefore, in the high frequency amplifier, the high frequency current attenuates and oscillations are suppressed even in this case.

On the other hand, when an attention is paid to the lines 3b and 3c, the first spacing L1 formed between these lines 3b and 3c is narrower than the second spacings L2 each of which is the spacing between the lines which make up the line pair. Therefore, there is a possibility that an electrical coupling occurs between the lines 3b and 3c.

If a coupling occurs between the lines 3b and 3c, a high frequency current applied to the line 3c flows not through the resistor 4 provided between the lines 3b and 3c, but through the above-mentioned coupling point into the line 3b. In this case, in the high frequency amplifier, a circulation flow passage (loop) in which the high frequency current applied to the line 3c flows through the above-mentioned coupling point into the line 3b, and then passes through the amplification element 1 and the input matching circuit and is applied again to the line 3c of the output matching circuit (transmission line 3) may be formed.

However, because the amplified high frequency current applied to the line 3c also flows through the resistor 4 provided between the lines 3c and 3d into the line 3d, as shown by a wide arrow in FIG. 3, the high frequency current attenuates because of this resistor 4. Therefore, in the high frequency amplifier, the increase in the high frequency current can be prevented and oscillations can be suppressed even in this case.

Further, in the high frequency amplifier according to Embodiment 1, not only the second spacings L2 but also the first spacing L1 narrower than the second spacings is formed by the lines 3b and 3c, as shown in FIGS. 2 and 3. Therefore, in the high frequency amplifier according to Embodiment 1, a further impedance reduction in the transmission line 3 is also implemented as compared with the case in which all the spacings are equal to the second spacings L2. More specifically, in the high frequency amplifier according to Embodiment 1, it is possible to implement both the suppression of oscillations, and an impedance reduction in the matching circuits (the input and output matching circuits).

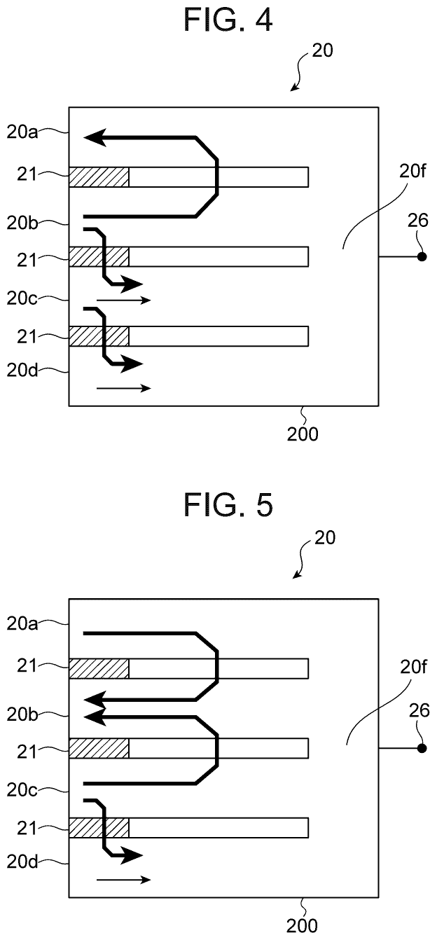

Here, the advantageous effect of the high frequency amplifier according to Embodiment 1 will be explained in more detail while referring to FIGS. 4 and 5. FIG. 4 shows an example of a comparison of flows of high frequency currents in a conventional high frequency amplifier with those shown in FIG. 2. Further, FIG. 5 shows an example of a comparison of flows of high frequency currents in the conventional high frequency amplifier with those shown in FIG. 3.

In FIGS. 4 and 5, reference sign 20 denotes a transmission line which the conventional high frequency amplifier includes. This transmission line 20 includes: a comb structure 200 having four lines 20a, 20b, 20c, and 20d arranged in parallel, and a joint part 20f; and resistors 21 each provided between adjacent lines out of the four lines, like the transmission line 3 in Embodiment 1.

Ends of the four lines 20a, 20b, 20c, and 20d are connected to four amplification elements (not illustrated) on a one to one basis via wires 2 (not illustrated). Further, the other ends of the four lines 20a, 20b, 20c, and 20d are joined together, thereby forming the joint part 20f. Further, reference sign 26 denotes an output terminal of the conventional high frequency amplifier.

In the transmission line 20, all spacings between lines are substantially the same, unlike in the transmission line 3 in Embodiment 1. Further, in the transmission line 20, all the spacings between lines are narrower than the above-mentioned second spacings L2.

For example, in the transmission line 20 shown in FIG. 4, a high frequency current with an opposite phase is applied only to the line 20a from an amplification element 1. Here, in the transmission line 20 shown in FIG. 4, because the spacing between the lines 20a and 20b is narrower than the above-mentioned second spacings L2, a coupling occurs between the lines 20a and 20b. As a result, a high frequency current applied to the line 20b flows through the point of the above-mentioned coupling directly into the line 20a, without flowing into the resistor 21 provided between the lines 20a and 20b, as shown by a wide arrow in FIG. 4.

In this case, in the conventional high frequency amplifier shown in FIG. 4, a circulation flow passage (loop) in which the high frequency current applied to the line 20b flows through the above-mentioned coupling point into the line 20a, and passes through the amplification element 1 and an input matching circuit and is applied again to the line 20b of an output matching circuit (transmission line 20) may be formed.

However, in the conventional high frequency amplifier shown in FIG. 4, there is a possibility that in the circulation flow passage (loop), the gain of the high frequency current cannot be attenuated and an oscillation occurs. Especially, when an attention is paid to the line 20a, there is no path in which the high frequency current is attenuated, unlike in the case of the line 20b. Therefore, in the conventional high frequency amplifier shown in FIG. 4, an oscillation occurs with a higher possibility than that in the high frequency amplifier according to Embodiment 1 shown in FIG. 2.

Further, as for a simple method of comparing the advantageous effect provided by the high frequency amplifier according to Embodiment 1 shown in FIG. 2, and that provided by the conventional high frequency amplifier shown in FIG. 4, there is a method of making a comparison in terms of the number of resistors which are present in the flow channels through which high frequency currents flow. For example, while three resistors 4 are present in the flow channels through which high frequency currents flow in the high frequency amplifier according to Embodiment 1 shown in FIG. 2, only two resistors 21 are present in the flow channels in the conventional high frequency amplifier shown in FIG. 4. That is to say, because the high frequency amplifier according to Embodiment 1 shown in FIG. 2 makes it possible to attenuate high frequency currents by means of a larger number of resistors than that in the conventional high frequency amplifier shown in FIG. 4, the effect of suppressing oscillations is also high.

Further, in the transmission line 20 shown in FIG. 5, a high frequency current with an opposite phase is applied only to the line 20b from an amplification element 1. Here, in the transmission line 20 shown in FIG. 5, because the spacing between the lines 20a and 20b and the spacing between the lines 20b and 20c are narrower than the above-mentioned second spacings L2, a coupling occurs between the lines 20a and 20b and a coupling occurs between the lines 20b and 20c.

As a result, a high frequency current applied to the line 20a flows through the point of the above-mentioned coupling directly into the line 20b without flowing into the resistor 21 provided between the lines 20a and 20b, as shown by a wide arrow in FIG. 5. Further, a high frequency current applied to the line 20c flows through the point of the above-mentioned coupling directly into the line 20b without flowing into the resistor 21 provided between the lines 20b and 20c.

In this case, in the conventional high frequency amplifier shown in FIG. 5, circulation flow passages (loops) in which the high frequency current applied to the line 20a and the high frequency current applied to the line 20c flow through the above-mentioned two coupling points into the line 20b, respectively, and pass through amplification elements 1 and the input matching circuit and are applied again to the lines 20a and 20c of the output matching circuit (transmission line 20) may be formed.

However, in the conventional high frequency amplifier shown in FIG. 5, there is a possibility that in the circulation flow passages (loops), the gains of the high frequency currents cannot be attenuated and oscillations occur. Especially, when an attention is paid to the lines 20a and 20b, there are no paths in which the high frequency currents are attenuated, unlike in the case of the line 20c. Therefore, in the conventional high frequency amplifier shown in FIG. 5, a parasitic oscillation occurs with a higher possibility than that in the high frequency amplifier according to Embodiment 1 shown in FIG. 3.

Further, as for a simple method of comparing the advantageous effect provided by the high frequency amplifier according to Embodiment 1 shown in FIG. 3, and that provided by the conventional high frequency amplifier shown in FIG. 5, there is a method of making a comparison in terms of the number of resistors which are present in the flow channels through which high frequency currents flow. For example, while two resistors 4 are present in the flow channels through which high frequency currents flow in the high frequency amplifier according to Embodiment 1 shown in FIG. 3, only one resistor 21 is present in the flow channel in the conventional high frequency amplifier shown in FIG. 5. That is to say, because the high frequency amplifier according to Embodiment 1 shown in FIG. 3 makes it possible to attenuate high frequency currents by means of a larger number of resistors than that in the conventional high frequency amplifier shown in FIG. 5, the effect of suppressing oscillations is also high.

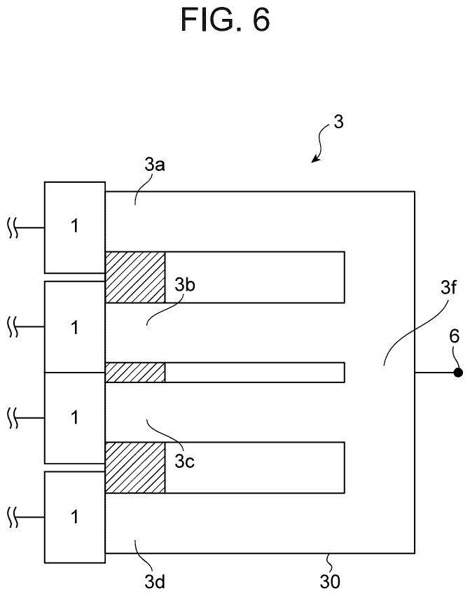

In the above-mentioned explanation, the example in which the output terminal of each of the four amplification elements 1 and an end of each of the lines 3a, 3b, 3c, and 3d which make up the transmission line 3 are connected via the wire 2 is explained. However, this wire 2 is not indispensable and may be omitted. In that case, the output terminal of each of the four amplification elements 1 is connected directly to the end of each of the lines 3a, 3b, 3c, and 3d which make up the transmission line 3, as shown in, for example, FIG. 6. In FIG. 6, for the sake of simplicity, the amplification elements 1 are shown by rectangular frames.

Further, although in the above-mentioned explanation, the example in which the high frequency amplifier is configured to include the four amplification elements 1 and the transmission line 3 is explained, multiple units each of which includes the four amplification elements 1 and the transmission line 3 may be provided in the high frequency amplifier.

Further, although in the above-mentioned explanation, the example in which each of the lines which make up the transmission line 3 has a linear shape is explained, each line does not necessarily have to have a linear shape. For example, in the transmission line 3, the effect of each electrical coupling between lines at a point connected to the resistor 4 is lower than that at any other point.

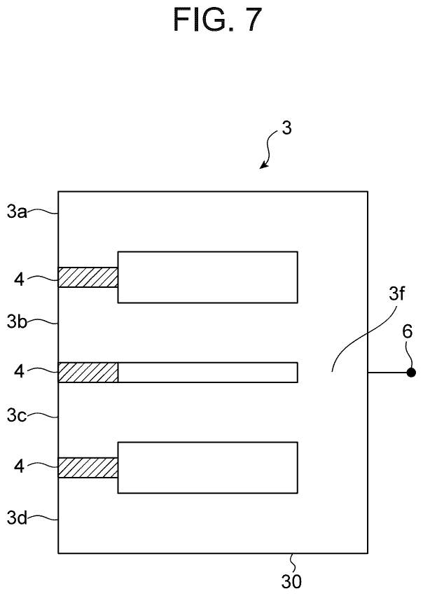

Accordingly, for example, the lines 3a and 3b forming the second spacing L2 may have a shape in which the lines protrude toward a corresponding resistor 4 in such a way as to be close to each other, at the parts where the lines are connected to the resistor 4, and the lines 3c and 3d forming the second spacing L2 may have a shape in which the lines protrude toward a corresponding resistor 4 in such a way as to be close to each other, at the parts where the lines are connected to the resistor 4, as shown in FIG. 7. In the case where the high frequency amplifier is configured in this way, the effect of the coupling between lines at their parts connected to the resistor 4, in the transmission line 3, is high compared with that in the case where each line has a linear shape, and high frequency currents easily flow into the resistor 4. As a result, the effect of suppressing oscillations is improved in the high frequency amplifier.

Further, in the above-mentioned explanation, the example in which the output matching circuit provided on the output terminal 6 side of the high frequency amplifier is constituted by the transmission line 3 is explained. However, either instead of or in addition to this configuration, the input matching circuit provided on the input terminal side of the high frequency amplifier may be constituted by the transmission line 3. More specifically, in the high frequency amplifying circuit, at least one of the input and output matching circuits has only to be constituted by the transmission line 3.

Further, although in the above-mentioned explanation, the example in which the four amplification elements 1 are provided (m=4) is explained, especially assuming that the number of amplification elements 1 is an even number greater than or equal to four, because every one of the lines forms one of the line pairs in the case where each of the line pairs is configured by combining two lines from an end of the transmission line in order along the direction in which the lines are arranged adjacent to each other, as mentioned above, the effect of suppressing oscillations is improved.

However, in the high frequency amplifier according to Embodiment 1, in case that the number of amplification elements 1 is an integer greater than or equal to three, a certain advantageous effect is provided.

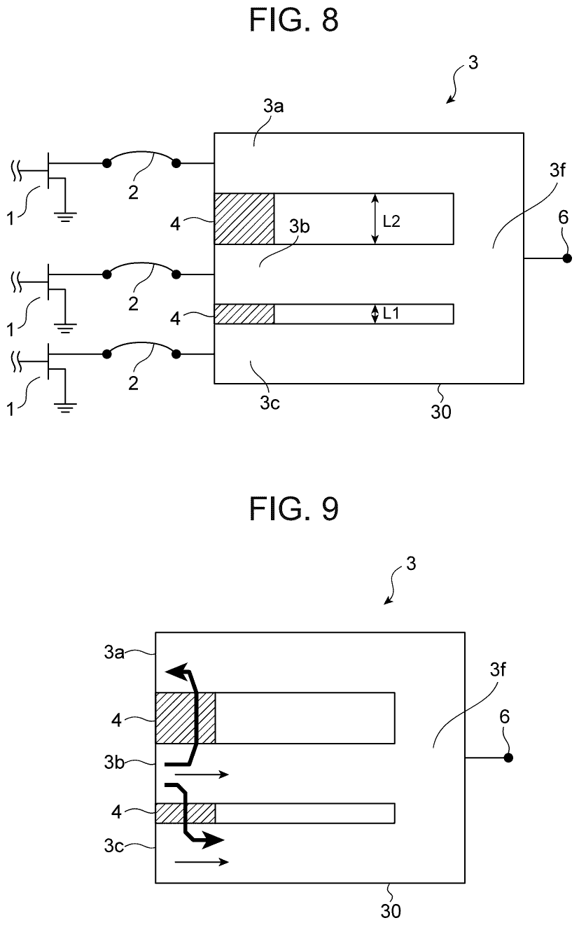

For example, in the high frequency amplifier, three amplification elements 1 may be provided (m=3), as shown in FIG. 8. In this case, the comb structure 30 which the transmission line 3 includes has three lines 3a, 3b, and 3c arranged in parallel.

Further, in the high frequency amplifier shown in FIG. 8, two or more spacings each formed between adjacent lines of the three lines 3a, 3b, and 3c (two spacings in this example) include a first spacing L1 and a second spacing L2 wider than the first spacing L1. In the example of FIG. 8, the spacing between the lines 3b and 3c is the first spacing L1, and the spacing between the lines 3a and 3b is the second spacing L2 wider than the first spacing L1.

An advantageous effect of the high frequency amplifier in this case will be explained while referring to FIG. 9.

FIG. 9 shows a case in which the amplification element 1 connected to the endmost line 3a, out of the three amplification elements 1, operates with an opposite phase, and the amplification elements 1 connected to the other lines 3b and 3c operate with the same phase. In this case, in the transmission line 3, a high frequency current with an opposite phase (in an opposite direction) is applied only to the line 3a from the amplification element 1.

In this case, because in the transmission line 3, the second spacing L2 which is sufficiently wide to be able to at least prevent the electrical coupling between the lines 3a and 3b is formed between the lines, no coupling occurs between these lines. Therefore, a high frequency current applied to the line 3b flows through the resistor 4 provided between the lines 3a and 3b into the line 3a, as shown by a wide arrow in FIG. 9, and attenuates because it flows through this resistor 4. Therefore, in the high frequency amplifier, the high frequency current attenuates and oscillations are suppressed.

Further, even when a slight coupling occurs between the lines 3a and 3b, if the impedance of the resistor 4 disposed between the lines is lower than the impedance between the lines at the point of this coupling, the high frequency current applied to the line 3b flows through the resistor 4 provided between the lines into the line 3a, instead of flowing through the above-mentioned coupling point into the line 3a. Therefore, in the high frequency amplifier, the high frequency current attenuates and oscillations are suppressed even in this case.

In addition, a case in which a circulation flow passage (loop) in which part or all of the high frequency current applied to the line 3b flows into the line 3a not through the resistor 4 provided between the lines 3a and 3b but through the above-mentioned coupling point, and then passes through the amplification element 1 and an input matching circuit and is applied again to the line 3b of the output matching circuit (transmission line 3) is formed is considered.

In this case, the amplified high frequency current applied to the line 3b flows through the resistor 4 provided between the lines 3b and 3c into the line 3c, as shown by a wide arrow in FIG. 9. The high frequency current applied to the line 3b flows through the resistor 4 into the adjacent line (the line 3c), as mentioned above, and hence attenuates. Therefore, in the high frequency amplifier according to Embodiment 1, even when a circulation flow passage (loop) as above is formed, the increase in the high frequency current can be prevented, and oscillations can be suppressed.

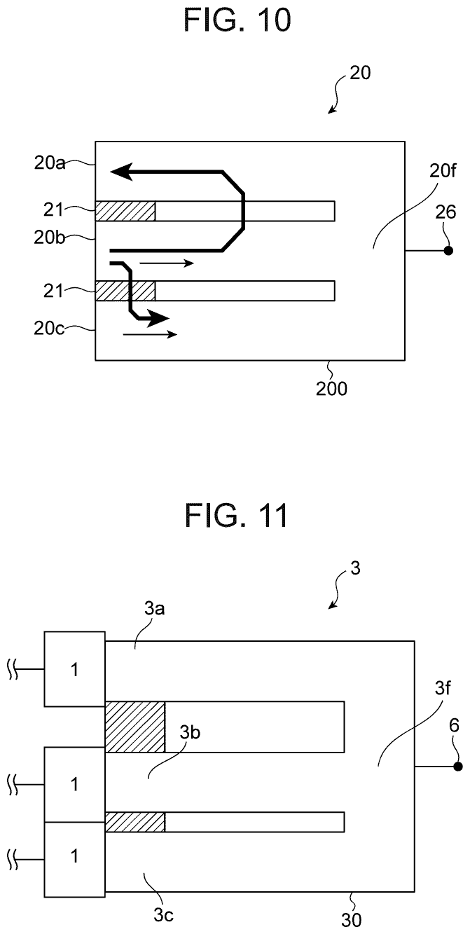

Here, the advantageous effect of the high frequency amplifier shown in FIG. 8 will be explained in more detail while referring to FIG. 10. FIG. 10 shows an example of a comparison of flows of high frequency currents in a conventional high frequency amplifier with those shown in 9.

In FIG. 10, reference sign 20 denotes a transmission line which the conventional high frequency amplifier includes. This transmission line 20 includes: a comb structure 200 having three lines 20a, 20b, and 20c arranged in parallel and a joint part 20f; and resistors 21 each provided between adjacent lines out of the three lines, like the transmission line 3 shown in FIG. 8.

Ends of the three lines 20a, 20b, and 20c are connected to three amplification elements (not illustrated) on a one to one basis via wires 2 (not illustrated). Further, the other ends of the three lines 20a, 20b, and 20c are joined together, thereby forming the joint part 3f. Further, reference sign 26 denotes an output terminal of the conventional high frequency amplifier.

In the transmission line 20, all spacings between lines are substantially the same, unlike in the transmission line 3 in Embodiment 1. Further, all the spacings between lines are narrower than the above-mentioned second spacing L2.

For example, in the transmission line 20 shown in FIG. 10, a high frequency current with an opposite phase is applied only to the line 20a from the amplification element 1. Here, in the transmission line 20 shown in FIG. 10, because the spacing between the lines 20a and 20b is narrower than the above-mentioned second spacing L2, coupling occurs between the lines 20a and 20b. As a result, a high frequency current applied to the line 20b flows through the above-mentioned coupling point directly into the line 20a without flowing into the resistor 21 provided between the lines 20a and 20b, as shown by a wide arrow in FIG. 10.

In this case, in the conventional high frequency amplifier shown in FIG. 10, a circulation flow passage (loop) in which the high frequency current applied to the line 20b flows through the above-mentioned coupling point into the line 20a, and passes through the amplification element 1 and an input matching circuit and is applied again to the line 20b of the output matching circuit (transmission line 20) may be formed.

However, in the conventional high frequency amplifier shown in FIG. 10, there is a possibility that in the circulation flow passage (loop), the gain of the high frequency current cannot be attenuated and an oscillation occurs. Especially, when an attention is paid to the line 20a, there is no path in which the high frequency current is attenuated, unlike in the case of the line 20b. Therefore, in the conventional high frequency amplifier shown in FIG. 10, an oscillation occurs with a higher possibility than that in the high frequency amplifier shown in FIG. 8.

Further, as for a simple method of comparing the advantageous effect provided by the high frequency amplifier shown in FIG. 8, and that provided by the conventional high frequency amplifier shown in FIG. 10, there is a method of making a comparison in terms of the number of resistors which are present in the flow channel through which a high frequency current flows. For example, while two resistors 4 are present in the flow channel through which a high frequency current flows in the high frequency amplifier according to Embodiment 1 shown in FIG. 8, only one resistor 21 is present in the flow channel in the conventional high frequency amplifier shown in FIG. 10. That is to say, because the high frequency amplifier shown in FIG. 8 makes it possible to attenuate the high frequency current by means of a larger number of resistors than that in the conventional high frequency amplifier shown in FIG. 10, the effect of suppressing oscillations is also high.

As mentioned above, in the high frequency amplifier according to Embodiment 1, in the case where the number of amplification elements 1 is an integer greater than or equal to three, it is possible to implement both the suppression of oscillations, and an impedance reduction in the matching circuits, by including the first spacing L1 and the second spacing L2 wider than the first spacing L1 in the multiple spacings each formed between adjacent lines.

In the above-mentioned explanation, the example in which the output terminal of each of the three amplification elements 1 and an end of each of the lines 3a, 3b, and 3c which make up the transmission line 3 are connected via the wire 2 is explained. However, this wire 2 is not indispensable and may be omitted. In that case, the output terminal of each of the three amplification elements 1 are connected directly to the end of each of the lines 3a, 3b, and 3c which make up the transmission line 3, as shown in, for example, FIG. 11. In FIG. 11, for the sake of simplicity, the amplification elements 1 are shown by rectangular frames.

Further, although in the above-mentioned explanation, the example in which the high frequency amplifier is configured to include the three amplification elements 1 and the transmission line 3 is explained, multiple units each of which includes the three amplification elements 1 and the transmission line 3 may be provided in the high frequency amplifier.

Further, although in the above-mentioned explanation, the example in which each of the lines which make up the transmission line 3 has a linear shape is explained, each line does not necessarily have to have a linear shape. For example, in the transmission line 3, the effect of each electrical coupling between lines at a point connected to the resistor 4 is lower than that at any other point.

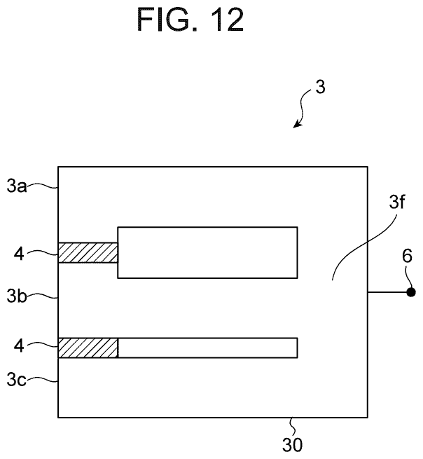

Accordingly, for example, the lines 3a and 3b forming the second spacing L2 may have a shape in which the lines protrude toward a corresponding resistor 4 in such a way as to be close to each other, at the parts where the lines are connected to the resistor 4, as shown in FIG. 12. In the case where the high frequency amplifier is configured in this way, the effect of the coupling between lines at their parts connected to the resistor 4, in the transmission line 3, is high compared with that in the case where each line has a linear shape, and a high frequency current easily flows into the resistor 4. Therefore, the effect of suppressing oscillations is improved in the high frequency amplifier.

Further, in the above-mentioned explanation, the example in which the output matching circuit provided on the output terminal 6 side of the high frequency amplifier is constituted by the transmission line 3 shown in FIG. 8 is explained. However, either instead of or in addition to this configuration, the input matching circuit provided on the input terminal side of the high frequency amplifier may be constituted by the transmission line 3 shown in FIG. 8. More specifically, in the high frequency amplifying circuit, at least one of the input and output matching circuits has only to be constituted by the transmission line 3 shown in FIG. 8.

Further, although the above-mentioned explanation is made by focusing on the case of m=3 or m=4, i.e. the case in which the number of amplification elements 1 is three or four, the number of amplification elements 1 may be an integer greater than or equal to three, e.g. five.

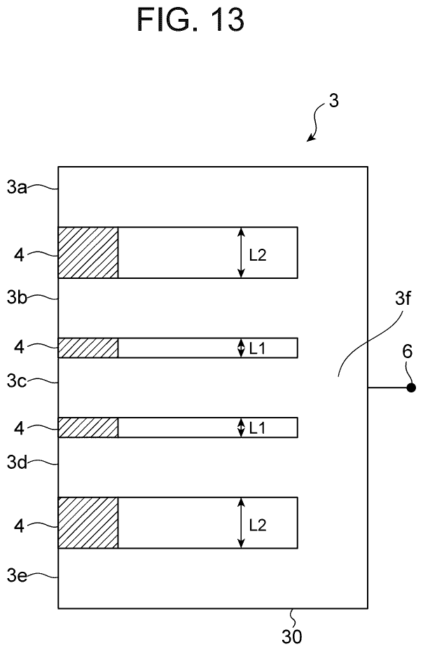

In this case, the high frequency amplifier includes an input matching circuit and an output matching circuit, and five amplification elements 1. Further, at least one of the input and output matching circuits includes: a comb structure 30 having five lines 3a, 3b, 3c, 3d, and 3e whose one ends are connected on a one to one basis to the five amplification elements 1, and a joint part 3f where the other ends of the five lines are joined together; and resistors 4 each provided between adjacent lines out of the five lines, as shown in FIG. 13.

Further, in at least one of the input and output matching circuits, multiple (four in this example) spacings each formed between adjacent lines of the five lines include first spacings L1 and second spacings L2 wider than the first spacings L1. Even in the case where the high frequency amplifier is configured in such a way that the number of amplification elements 1 is five, as mentioned above, the high frequency amplifier makes it possible to implement both the suppression of oscillations, and an impedance reduction in the matching circuits, like in the case where the number of amplification elements 1 is three or four.

As mentioned above, according to this Embodiment 1, a high frequency amplifier includes an input matching circuit, an output matching circuit, and m (m is an integer greater than or equal to three) amplification elements 1, and at least one of the input and output matching circuits includes: a comb structure 30 having m lines whose one ends are connected on a one to one basis to the m amplification elements 1, and a joint part 3f where the other ends of the m lines are joined together; and resistors 4 each provided between adjacent lines out of the m lines, and multiple spacings each formed between adjacent lines of the m lines include a first spacing L1 and a second spacing L2 wider than the first spacing L1. As a result, the high frequency amplifier according to Embodiment 1 makes it possible to implement both the suppression of oscillations, and an impedance reduction in the matching circuits.

Further, m is an even number greater than or equal to four, and in the comb structure 30, each of line pairs is configured by combining adjacent two lines, out of the m lines, from an end of the comb structure in order along a direction in which the m lines are arranged adjacent to each other, and the spacing between the line pairs is the first spacing L1 and the spacing between the lines which make up each of the line pairs is the second spacing L2. As a result, because in the high frequency amplifier according to Embodiment 1, every one of the m lines which make up the comb structure 30 forms one of the line pairs, the effect of suppressing oscillations is improved.

Further, the second spacing L2 is wide enough to be able to at least prevent the electrical coupling between the lines which form the second spacing L2. As a result, in the high frequency amplifier according to Embodiment 1, the effect of suppressing oscillations is improved.

Further, according to this Embodiment 1, a matching circuit includes: a comb structure 30 having m lines whose one ends are connected on a one to one basis to m (m is an integer greater than or equal to three) amplification elements 1, and a joint part 3f where the other ends of the m lines are joined together; and resistors 4 each provided between adjacent lines out of the m lines, and multiple spacings each formed between adjacent lines of the m lines include a first spacing L1 and a second spacing L2 wider than the first spacing L1. As a result, the matching circuit according to Embodiment 1 also makes it possible to suppress oscillations in a high frequency amplifier including the amplification elements 1 while achieving an impedance reduction.

Further, in the matching circuit, m is an even number greater than or equal to four, and in the comb structure 30, each of line pairs is configured by combining adjacent two lines, out of the m lines, from an end of the comb structure in order along a direction in which the m lines are arranged adjacent to each other, and the spacing between the line pairs is the first spacing L1 and the spacing between the lines which make up each of the line pairs is the second spacing L2. As a result, because in the matching circuit according to Embodiment 1, every one of the m lines which make up the comb structure 30 forms one of the line pairs, the effect of suppressing oscillations in the high frequency amplifier including the amplification elements 1 is improved.

### Embodiment 2

In Embodiment 1, the high frequency amplifiers that can implement both the suppression of oscillations, and an impedance reduction in matching circuits are explained. In Embodiment 2, a high frequency amplifier that can implement both the suppression of oscillations, and an impedance reduction in matching circuits more surely will be explained.

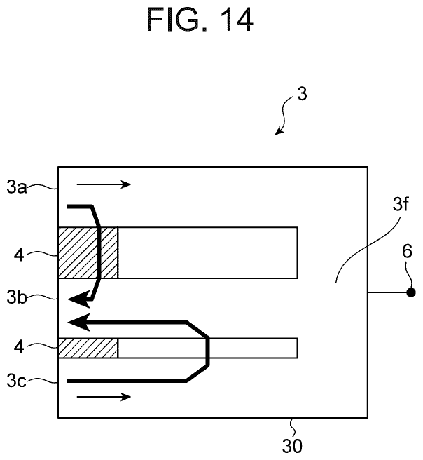

In Embodiment 1, there is a case in which in the high frequency amplifier shown in FIG. 8, the amplification element 1 connected to the line 3b, out of the three amplification elements 1, operates with an opposite phase, and the amplification elements 1 connected to the other lines 3a and 3c operate with the same phase. An example of flows of high frequency currents in that case is shown in FIG. 14.

As shown in FIG. 14, in the above-mentioned case, because in the transmission line 3, the second spacing L2 which is sufficiently wide to be able to at least prevent the electrical coupling between the lines 3a and 3b is formed between the lines, no coupling occurs between the lines. Therefore, a high frequency current applied to the line 3b flows through the resistor 4 provided between the lines 3a and 3b into the line 3a, as shown by a wide arrow in FIG. 14, and attenuates because it flows through this resistor 4. Therefore, in the high frequency amplifier, the high frequency current attenuates and oscillations are suppressed.

Further, even when a slight coupling occurs between the lines 3a and 3b, if the impedance of the resistor 4 provided between the lines is lower than the impedance between the lines at the point of this coupling, the high frequency current applied to the line 3b flows through the resistor 4 provided between the lines into the line 3a, instead of flowing through the above-mentioned coupling point into the line 3a. Therefore, in the high frequency amplifier, the high frequency current attenuates and oscillations are suppressed even in this case.

On the other hand, when an attention is paid to the lines 3b and 3c, the first spacing L1 formed between these lines 3b and 3c is narrower than the second spacing L2 formed between the lines 3a and 3b. Therefore, an electrical coupling may occur between the lines 3b and 3c.

If a coupling occurs between the lines 3b and 3c, a high frequency current applied to the line 3c flows not through the resistor 4 provided between the lines 3b and 3c, but through the above-mentioned coupling point into the line 3b, as shown by a wide arrow in FIG. 14. In this case, in the high frequency amplifier, a circulation flow passage (loop) in which the high frequency current applied to the line 3c flows through the above-mentioned coupling point into the line 3b, and passes through an amplification element 1 and the input matching circuit and is applied again to the line 3c of the output matching circuit (transmission line 3) may be formed. In that case, there is a possibility that in the high frequency amplifier, the high frequency current increases in the loop formed between the input and output matching circuits, and an oscillation occurs.

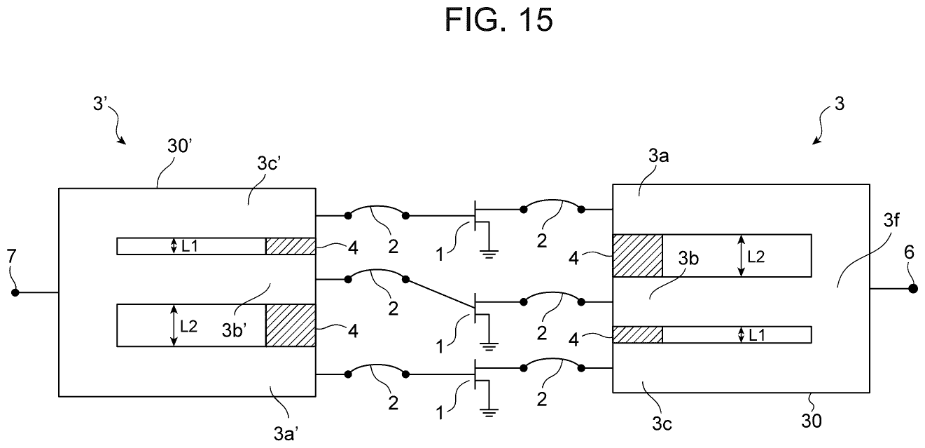

Therefore, the high frequency amplifier according to Embodiment 2 is configured in such a way as shown in, for example, FIG. 15, in order to enhance the effect of suppressing oscillations.

As shown in FIG. 15, in the high frequency amplifier according to Embodiment 2, while an output matching circuit is configured by a transmission line 3, an input matching circuit is configured by a transmission line 3′.

The transmission line 3′ which configures the input matching circuit includes: a comb structure 30′ having three lines 3a′, 3b′, and 3c′ whose one ends are connected on a one to one basis to input terminals of three amplification elements 1, and a joint part 3f where the other ends of the three lines are joined together; and resistors 4 each provided between adjacent lines out of the three lines. Reference sign 7 denotes an input terminal of the high frequency amplifier according to Embodiment 2.

Similarly, the transmission line 3 which configures the output matching circuit includes: a comb structure 30 having three lines 3a, 3b, and 3c whose one ends are connected on a one to one basis to input terminals of the three amplification elements 1, and a joint part 3f where the other ends of the three lines are joined together; and resistors 4 each provided between adjacent lines out of the three lines.

Further, in the transmission line 3′ on the input side and the transmission line 3 on the output side, each of multiple spacings (two spacings in this case) is formed between adjacent lines of the three lines, and the multiple spacings formed include a first spacing L1 and a second spacing L2 wider than the first spacing L1, as shown in FIG. 15. Then, the transmission line 3′ on the input side and the transmission line 3 on the output side are arranged across the three amplification elements 1 in such a way that the first spacing L1 and the second spacing L2 face each other.

In this case, even when in the transmission line 3 on the output side, a high frequency current with an opposite phase applied to the line 3c flows not through the resistor 4 provided between the lines 3b and 3c, but through the point of a coupling occurring between the lines 3b and 3c into the line 3b, for example, as shown in FIG. 14, this high frequency current is amplified by the amplification element 1 connected via a wire 2 to the line 3b, and is applied to the line 3b′ which the transmission line 3′ on the input side has.

On the other hand, because on the input side, the second spacing L2 which is sufficiently wide to be able to at least prevent the electrical coupling between the lines 3a′ and 3b′ is formed between the lines, no coupling occurs between these lines. Therefore, a high frequency current applied to the line 3b′ flows through the resistor 4 provided between the lines 3a′ and 3b′ into the line 3a′, and attenuates because it flows through this resistor 4.

As mentioned above, in the high frequency amplifier according to Embodiment 2, the transmission line 3′ on the input side and the transmission line 3 on the output side are arranged across the three amplification elements 1 in such a way that the first spacing L1 and the second spacing L2 face each other. Therefore, in the high frequency amplifier according to Embodiment 2, a high frequency current can be made to pass through a resistor 4 on either one of the input and output sides more surely. As a result, in the high frequency amplifier according to Embodiment 2, the increase in the high frequency current in the circulation flow passage (loop) formed between the input and output matching circuits can be prevented and oscillations can be suppressed.

As mentioned above, according to this Embodiment 2, the high frequency amplifier includes the input matching circuit, the output matching circuit, and the m (m is an integer greater than or equal to three) amplification elements, and the input matching circuit includes: the comb structure 30′ having the m lines whose one ends are connected on a one to one basis to the input terminals of the m amplification elements 1, and the joint part 3f where the other ends of the m lines are joined together; and the resistors 4 each provided between adjacent lines out of the m lines, and the output matching circuit includes: the comb structure 30 having the m lines whose one ends are connected on a one to one basis to the output terminals of the m amplification elements 1, and the joint part 3f where the other ends of the m lines are joined together; and the resistors 4 each provided between adjacent lines out of the m lines, and, in each of the input and output matching circuits, the multiple spacings each formed between adjacent lines of the m lines include the first spacing L1 and the second spacing L2 wider than the first spacing L1, and the input and output matching circuits are arranged across the amplification elements 1 in such a way that the first spacing L1 and the second spacing L2 face each other. As a result, the high frequency amplifier according to Embodiment 2 can implement both the suppression of oscillations, and an impedance reduction in the matching circuits more surely compared with that according to Embodiment 1.

It is to be understood that any combination of the above-mentioned embodiments can be made, various changes can be made in any component according to any one of the above-mentioned embodiments, or any component according to any one of the above-mentioned embodiments can be omitted. For example, the transmission line 3 in the case of m=4, which is explained in Embodiment 1, may be applied to Embodiment 2, so that the input and output matching circuits are configured by transmission lines each including four lines, and the input and output matching circuits are arranged across the amplification elements 1 in such a way that a first spacing L1 and a second spacing L2 face each other.

### INDUSTRIAL APPLICABILITY

The present disclosure can implement both the suppression of oscillations, and an impedance reduction in matching circuits, and is suitable for use in high frequency amplifiers.

### REFERENCE SIGNS LIST

1 amplification element, 2 wire, 3 transmission line, 3′ transmission line, 3a line, 3a′ line, 3ab line pair, 3b line, 3b′ line, 3c line, 3c′ line, 3cd line pair, 3d line, 3f joint part, 3f joint part, 4 resistor, 6 output terminal of high frequency amplifier, 7 input terminal of high frequency amplifier, 20 transmission line, 20a line, 20b line, 20c line, 20d line, 21 resistor, 30 comb structure, 30′ comb structure, L1 first spacing, and L2 second spacing.

1. A high frequency amplifier including an input matching circuit, an output matching circuit, and m amplification elements, wherein
m is an integer greater than or equal to three,
at least one of the input and output matching circuits includes:
a comb structure having m lines whose one ends are connected on a one to one basis to the m amplification elements, and a joint part where other ends of the m lines are joined together; and
resistors each provided between adjacent lines out of the m lines,
and wherein multiple spacings each formed between adjacent lines of the m lines include a first spacing and a second spacing wider than the first spacing.

2. The high frequency amplifier according to claim 1, wherein m is an even number greater than or equal to four, and in the comb structure, each of line pairs is configured by combining adjacent two lines, out of the m lines, from an end of the comb structure in order along a direction in which the m lines are arranged adjacent to each other, and wherein a spacing between the line pairs is the first spacing and a spacing between the lines which make up each of the line pairs is the second spacing.

3. A high frequency amplifier including an input matching circuit, an output matching circuit, and m amplification elements, wherein
m is an integer greater than or equal to three,
the input matching circuit includes:
a comb structure having m lines whose one ends are connected on a one to one basis to input terminals of the m amplification elements, and a joint part where other ends of the m lines are joined together; and
resistors each provided between adjacent lines out of the m lines, and
the output matching circuit includes:
a comb structure having m lines whose one ends are connected on a one to one basis to output terminals of the m amplification elements, and a joint part where other ends of the m lines are joined together; and
resistors each provided between adjacent lines out of the m lines,
and wherein in each of the input and output matching circuits, multiple spacings each formed between adjacent lines of the m lines include a first spacing and a second spacing wider than the first spacing, and the input and output matching circuits are arranged across the amplification elements in such a way that the first spacing and the second spacing face each other.

4. The high frequency amplifier according to claim 1, wherein the second spacing is wide enough to be able to at least prevent an electrical coupling between lines which form the second spacing.

5. The high frequency amplifier according to claim 3, wherein the second spacing is wide enough to be able to at least prevent an electrical coupling between lines which form the second spacing.

6. A matching circuit comprising:
a comb structure having m lines whose one ends are connected on a one to one basis to m amplification elements, and a joint part where other ends of the m lines are joined together; and
resistors each provided between adjacent lines out of the m lines, wherein multiple spacings each formed between adjacent lines of the m lines include a first spacing and a second spacing wider than the first spacing,
wherein m is an integer greater than or equal to three.

7. The matching circuit according to claim 6, wherein m is an even number greater than or equal to four, and in the comb structure, each of line pairs is configured by combining adjacent two lines, out of the m lines, from an end of the comb structure in order along a direction in which the m lines are arranged adjacent to each other, and wherein a spacing between the line pairs is the first spacing and a spacing between the lines which make up each of the line pairs is the second spacing.
